(19) United States
(12) Patent Application Publication
(10) Pub. No.: US 2026/0114061 A1
(43) Pub. Date: Apr. 23, 2026

(54) SENSOR PACKAGE STRUCTURE, SENSING MODULE, AND MANUFACTURING METHOD OF SENSING MODULE

(71) Applicant: TONG HSING ELECTRONIC INDUSTRIES, LTD., Taoyuan City (TW)

(72) Inventors: Xie-Zhe He, Taipei City (TW); SIN-CHUN LI, Taipei City (TW); Sheng-Feng Kao, Taoyuan City (TW); CHIA-MIN WU, Taoyuan City (TW); Kuan-Hsun Wu, Taoyuan City (TW)

(21) Appl. No.: 18/981,609

(22) Filed: Dec. 15, 2024

(30) Foreign Application Priority Data
Oct. 23, 2024 (TW) 113140255

(51) Int. Cl. H10F 39/00; H10F 39/12; H10F 71/00

(52) U.S. Cl. CPC H10F 39/804; H10F 39/011; H10F 39/12; H10F 71/136

(57) ABSTRACT

A sensor package structure, a sensing module, and a manufacturing method of a sensing module are provided. The sensing module includes a sensor chip and a cap. A top surface of the sensor chip has a sensing region and a carrying region arranged outside of the sensing region. The cap includes a light-permeable sheet and an opaque adhesive layer. An inner surface of the light-permeable sheet has a light-permeable region and a processing region that surrounds the light-permeable region. The opaque adhesive layer has an annular shape and is adhered onto the processing region. The opaque adhesive layer is configured to allow a laser beam to pass therethrough. The cap is adhered to the carrying region through the opaque adhesive layer, such that the cap and the sensor chip jointly define an enclosed space, and the light-permeable region faces toward the sensing region of the sensor chip.

### CROSS-REFERENCE TO RELATED PATENT APPLICATION

This application claims the benefit of priority to Taiwan Patent Application No. 113140255, filed on Oct. 23, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a sensing mechanism, and more particularly to a sensor package structure, a sensing module, and a manufacturing method of a sensing module.

### BACKGROUND OF THE DISCLOSURE

A conventional sensing module has a light-permeable sheet that is prepared by using a cutter to slice a light-permeable board. However, since a slicing loss of the light-permeable board that is ground away by the cutter is too high during the slicing process (e.g., a removed part of the light-permeable board ground by the cutter, i.e., a slicing loss, having a width of 100 μm or more), exorbitant material costs can be incurred in the conventional sensing module.

### SUMMARY OF THE DISCLOSURE

In response to the above-referenced technical inadequacies, the present disclosure provides a sensor package structure, a sensing module, and a manufacturing method of a sensing module for effectively improving on the issues associated with conventional sensing modules.

In order to solve the above-mentioned problems, one of the technical aspects adopted by the present disclosure is to provide a manufacturing method of a sensing module, which includes a preparing step, an adhesive placing step, a stealth dicing (SD) step, a cracking step, and a bonding step. The preparing step is implemented by attaching an outer surface of a light-permeable board onto a tape. The light-permeable board defines a plurality of processing paths that jointly define a plurality of light-permeable sheets connected to each other. An inner surface of each of the light-permeable sheets has a light-permeable region and a processing region that surrounds the light-permeable region. The adhesive placing step is implemented by respectively disposing a plurality of opaque adhesive layers on the processing regions of the light-permeable sheets. Each of the opaque adhesive layers surrounds the light-permeable region of a corresponding one of the light-permeable sheets and allows a laser beam to pass therethrough. The opaque adhesive layers are spaced apart from each other, and any two of the opaque adhesive layers adjacent to each other have a gap therebetween. A width of each of the gaps is less than or equal to 90 μm, and the processing paths are arranged in the gaps. The SD step is implemented by emitting the laser beam onto the light-permeable board along the processing paths so as to form a plurality of first modified points in an interior of the light-permeable board at a first depth and a plurality of second modified points in the interior of the light-permeable board at a second depth that is different from the first depth. The cracking step is implemented by stretching the tape to crack the light-permeable board into the light-permeable sheets along the processing paths through the first modified points and the second modified points. Each of the light-permeable sheets and the corresponding opaque adhesive layer adhered thereon are jointly defined as one of a plurality of caps. The bonding step is implemented by attaching one of the caps onto a sensor chip through the opaque adhesive layer thereof that surrounds a sensing region of the sensor chip, such that the one of the caps and the sensor chip jointly define an enclosed space, and the light-permeable region of the light-permeable sheet faces toward the sensing region of the sensor chip.

In order to solve the above-mentioned problems, another one of the technical aspects adopted by the present disclosure is to provide a sensor package structure, which includes a substrate, a sensor chip, a cap, and an encapsulant. The substrate has a first surface and a second surface that is opposite to the first surface. The sensor chip is mounted on the first surface of the substrate and is electrically coupled to the substrate. A top surface of the sensor chip has a sensing region and a carrying region that is arranged outside of the sensing region. The cap includes a light-permeable sheet and an opaque adhesive layer. The light-permeable sheet has an inner surface and an outer surface that is opposite to the inner surface. The inner surface has a light-permeable region and a processing region that surrounds the light-permeable region. The opaque adhesive layer is ring-shaped and is adhered onto the processing region of the inner surface of the light-permeable sheet. The opaque adhesive layer is configured to allow a laser beam to pass therethrough. The cap is adhered onto the carrying region of the sensor chip through the opaque adhesive layer, the cap and the top surface of the sensor chip jointly define an enclosed space, and the light-permeable region of the light-permeable sheet faces toward the sensing region of the sensor chip. The encapsulant is formed on the first surface of the substrate. The sensor chip and the cap are embedded in the encapsulant, and at least part of the outer surface of the light-permeable sheet is exposed from the encapsulant.

In order to solve the above-mentioned problems, yet another one of the technical aspects adopted by the present disclosure is to provide a sensing module, which includes a sensor chip and a cap. A top surface of the sensor chip has a sensing region and a carrying region that is arranged outside of the sensing region. The cap includes a light-permeable sheet and an opaque adhesive layer. The light-permeable sheet has an inner surface and an outer surface that is opposite to the inner surface. The inner surface has a light-permeable region and a processing region that surrounds the light-permeable region. The opaque adhesive layer is ring-shaped and is adhered onto the processing region of the inner surface of the light-permeable sheet. The opaque adhesive layer is configured to allow a laser beam to pass therethrough. The cap is adhered onto the carrying region of the sensor chip through the opaque adhesive layer, the cap and the top surface of the sensor chip jointly define an enclosed space, and the light-permeable region of the light-permeable sheet faces toward the sensing region of the sensor chip.

Therefore, the steps in the manufacturing method of the sensing module provided by the present disclosure are implemented through certain components (e.g., the opaque adhesive layers) for enabling the SD step to be applied to the light-permeable board, so that when the light-permeable board is cracked to become the light-permeable sheets, material loss of the light-permeable board can be greatly reduced to effectively decrease production costs.

Moreover, the sensor package structure, the manufacturing method, and the sensing module in the present disclosure can be implemented to enable the sensor chip to be assembled with the cap having the adhering function, thereby facilitating the production and manufacturing of the sensing module (or the sensor package structure).

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view showing a preparing step of a manufacturing method of a sensing module according to one embodiment of the present disclosure;

FIG. 2 is a schematic perspective view showing an adhesive placing step of the manufacturing method;

FIG. 3 is a schematic perspective view showing a stealth dicing (SD) step of the manufacturing method;

FIG. 4 is a schematic view showing a first implementation process of FIG. 3;

FIG. 5 is a schematic view showing a second implementation process of FIG. 3;

FIG. 6 is a schematic view showing a third implementation process of FIG. 3;

FIG. 7 is a schematic planar view showing a cracking step of the manufacturing method;

FIG. 8 is a schematic perspective view showing the cracking step of the manufacturing method;

FIG. 9 is a schematic perspective view showing a bonding step of the manufacturing method;

FIG. 10 is a schematic perspective view of a sensor package structure according to the embodiment of the present disclosure;

FIG. 11 is a schematic cross-sectional view taken along line XI-XI of FIG. 10; and

FIG. 12 is a schematic enlarged view of part XII of FIG. 9.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on. ” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### Manufacturing Method of Sensing Module

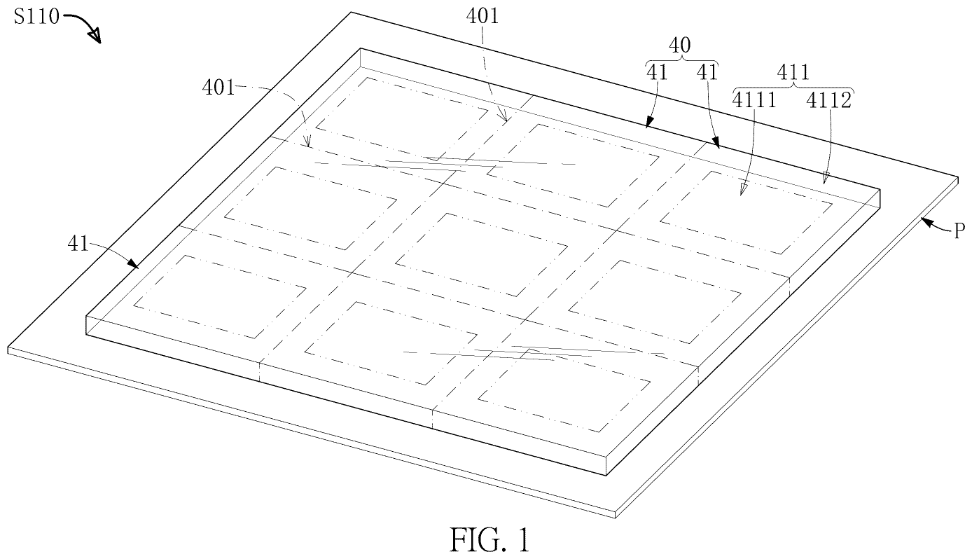

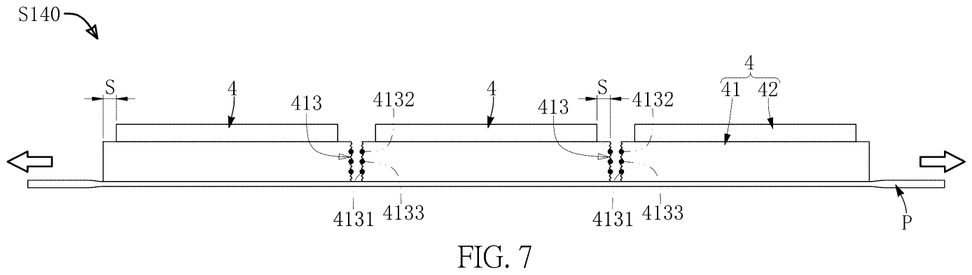

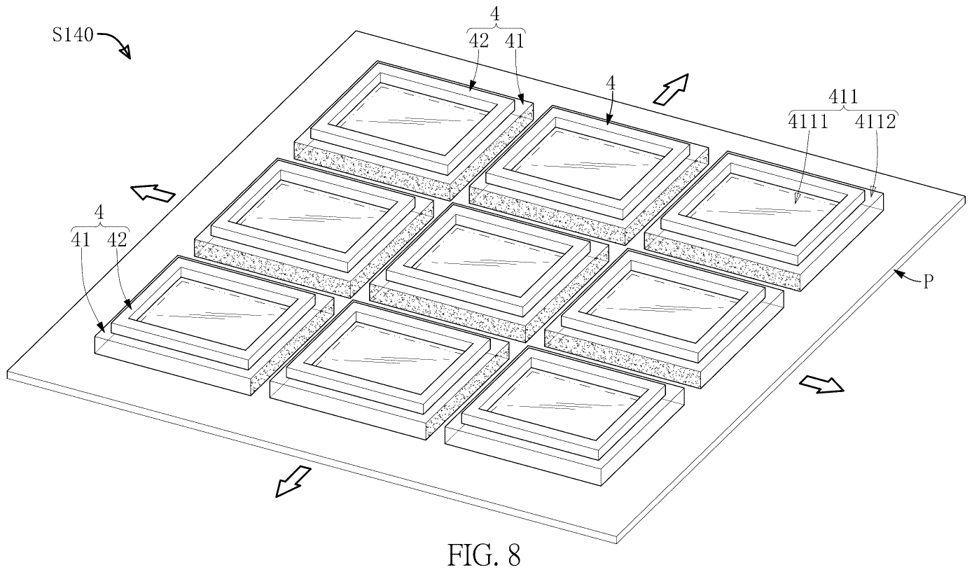

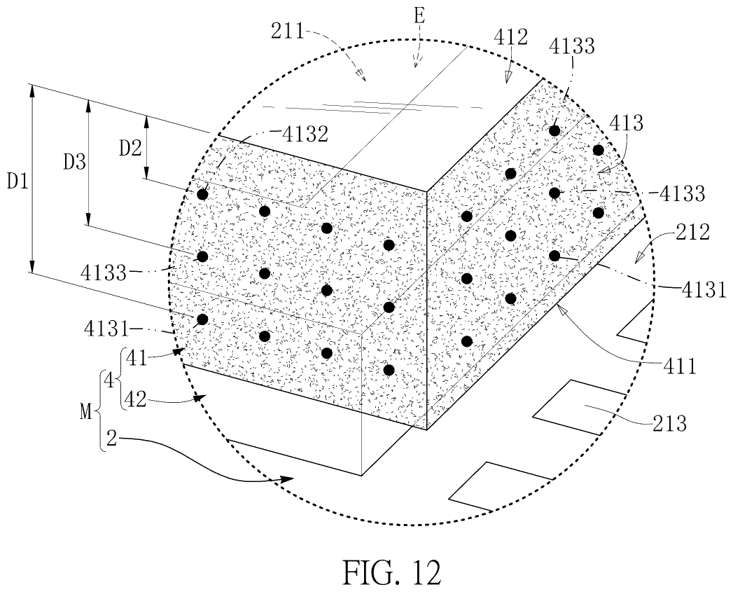

Referring to FIG. 1 to FIG. 12, an embodiment of the present disclosure is provided. As shown in FIG. 1 to FIG. 9, the present embodiment provides a manufacturing method of a sensing module that sequentially includes or implements a preparing step S110, an adhesive placing step S120, a stealth dicing (SD) step S130, a cracking step S140, and a bonding step S150, but the present disclosure is not limited thereto. The following description describes each step of the manufacturing method.

As shown in FIG. 1, the preparing step S110 is implemented by attaching an outer surface of a light-permeable board 40 onto a tape P. The light-permeable board 40 can be a transparent glass board and defines a plurality of processing paths 401 that jointly define a plurality of light-permeable sheets 41 connected to each other. The tape P is preferably provided with a property of elastic stretch. The processing paths 401 in the present embodiment includes a plurality of longitudinal paths and a plurality of transverse paths that are perpendicular to the longitudinal paths, so that the light-permeable sheets 41 are substantially in a matrix arrangement, but the present disclosure is not limited thereto.

Specifically, an inner surface 411 of each of the light-permeable sheets 41 has a light-permeable region 4111 and a processing region 4112 that surrounds the light-permeable region 4111. In the present embodiment, the processing region 4112 of each of the light-permeable sheets 41 is substantially ring-shaped, and the light-permeable sheets 41 are connected to each other through the processing region 4112.

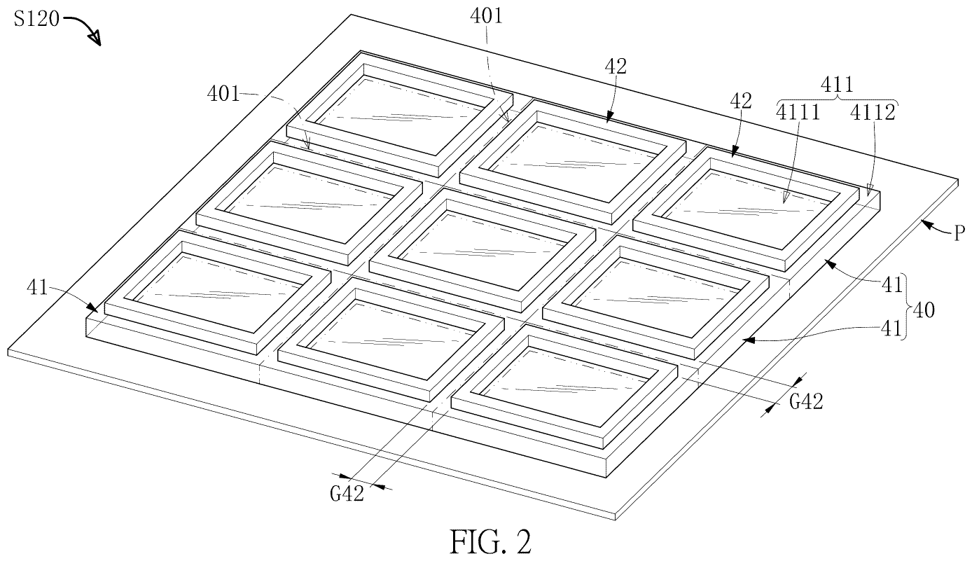

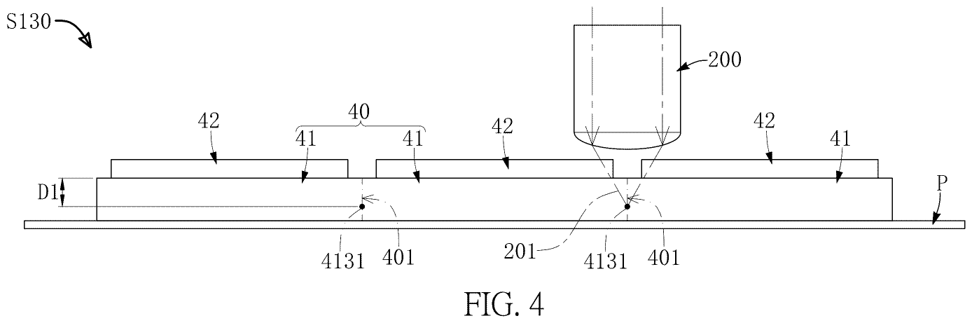

As shown in FIG. 2, the adhesive placing step S120 is implemented by respectively disposing a plurality of opaque adhesive layers 42 on the processing regions 4112 of the light-permeable sheets 41. Specifically, each of the opaque adhesive layers 42 surrounds the light-permeable region 4112 of a corresponding one of the light-permeable sheets 41. Moreover, each of the opaque adhesive layers 42 is sticky and can block visible light from passing therethrough, but each of the opaque adhesive layers 42 allows a laser beam 201 emitted from a SD apparatus 200 to pass therethrough (as shown in FIG. 4). In other words, the opaque adhesive layer 42 provided by the present embodiment is different from a shielding layer that allows visible light to pass therethrough, that does not allow the laser beam 201 to pass therethrough, or that is not sticky.

Specifically, the opaque adhesive layers 42 disposed on the light-permeable sheets 41 are spaced apart from each other, and any two of the opaque adhesive layers 42 adjacent to each other have a gap G42 therebetween. Furthermore, a width of each of the gaps G42 is less than or equal to 90 μm, and the processing paths 401 are arranged in the gaps G. It should be noted that the width of any one of the gaps G42 is preferably within a range from 10 μm to 30 μm.

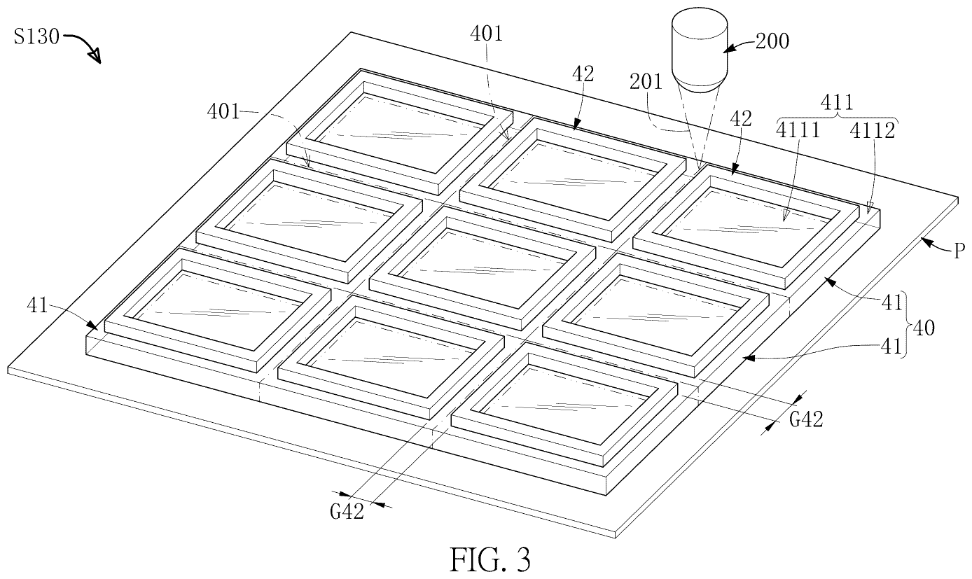

As shown in FIG. 3 to FIG. 6, the SD step S130 is implemented by emitting the laser beam 201 onto the light-permeable board 40 along the processing paths 401 so as to form a plurality of first modified points 4131 in an interior of the light-permeable board 40 at a first depth D1 and a plurality of second modified points 4132 in the interior of the light-permeable board 40 at a second depth D2 that is different from the first depth D1. In other words, the laser beam 201 focuses in the interior of the light-permeable board 40 by passing through any one of the opaque adhesive layers 42, thereby forming the first modified points 4131 and the second modified points 4132.

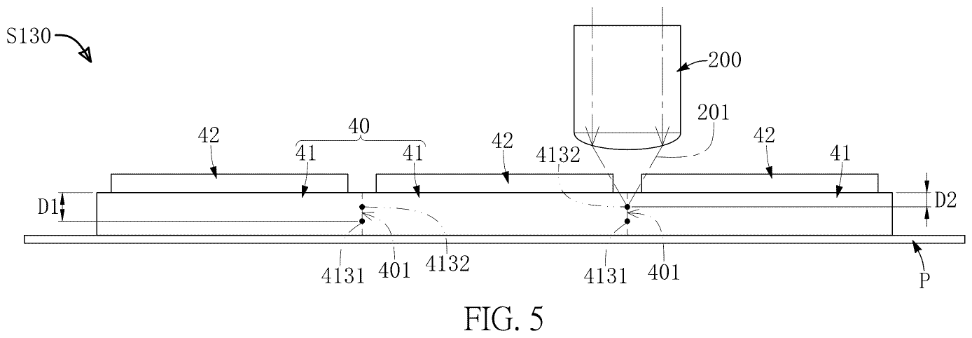

In the present embodiment, the first modified points 4131 are substantially located at a plane adjacent to the tape P, and the second modified points 4132 are substantially located at another plane away from the tape P. Moreover, the SD step S130 shown in FIG. 4 and FIG. 5 is implemented to form the first modified points 4131 and the second modified points 4132 at two different depths according to a thickness of the light-permeable board 40 or other design requirements, but the present disclosure is not limited thereto.

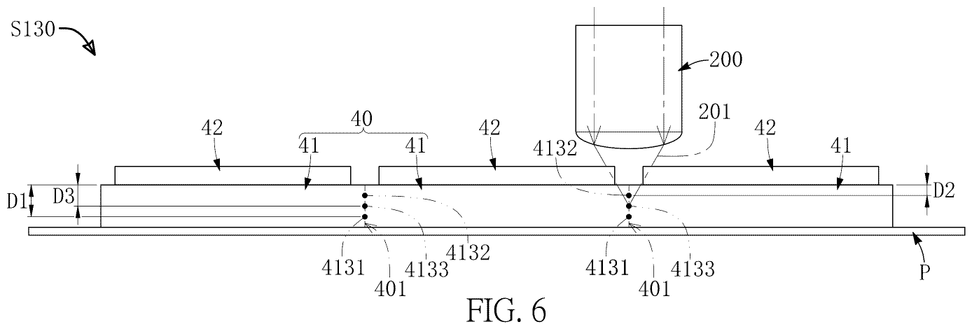

For example, as shown in FIG. 6, the laser beam 201 is emitted onto the light-permeable board 40 along the processing paths 401 so as to form at least one third modified point 4133 in the interior of the light-permeable board 40 (at a third depth D3) between any one of the first modified points 4131 and an adjacent one of the second modified points 4132. In the present embodiment, the at least one third modified point 4133 is spaced apart from an adjacent one of the first modified points 4131 and an adjacent one of the second modified points 4132 by a same distance, but the present disclosure is not limited thereto.

In other embodiments of the present disclosure not shown in the drawings, a quantity of the at least one third modified point 4133 between any one of the first modified points 4131 and an adjacent one of the second modified points 4132 can be more than one, and the third modified points 4133 can be arranged at different depths.

As shown in FIG. 6 to FIG. 8, the cracking step S140 is implemented by stretching the tape P (along a direction perpendicular to the light-permeable board 40) to crack the light-permeable board 40 into the light-permeable sheets 41 along the processing paths 401 through the first modified points 4131 and the second modified points 4132. Each of the light-permeable sheets 41 and the corresponding opaque adhesive layer 42 adhered thereon are jointly defined as one of a plurality of caps 4.

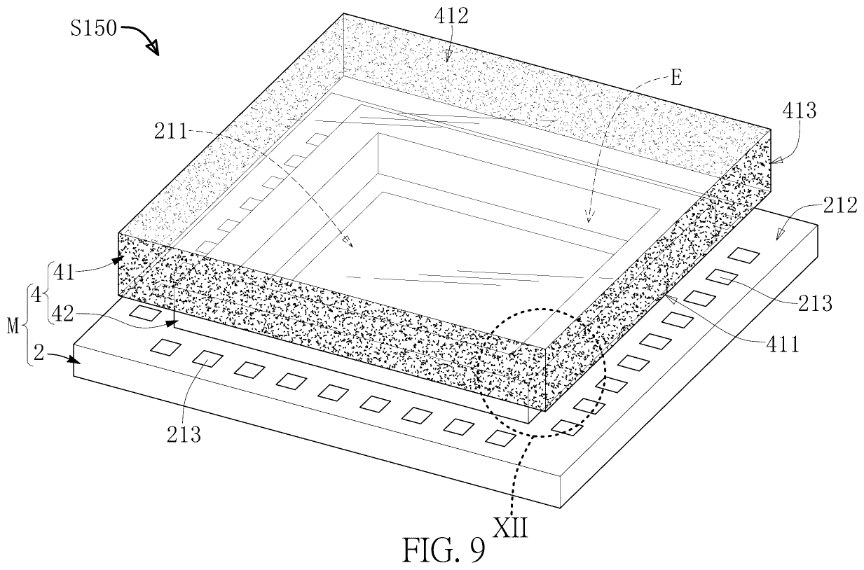

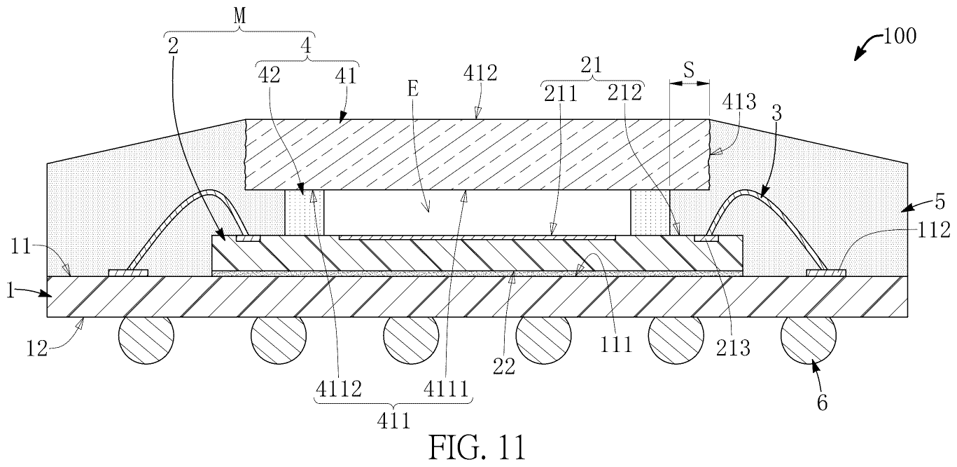

As shown in FIG. 9, the bonding step S150 is implemented by attaching one of the caps 4 onto a sensor chip 2 through the opaque adhesive layer 42 thereof that surrounds a sensing region 211 of the sensor chip 2, such that the one of the caps 4 and the sensor chip 2 jointly define an enclosed space E, and the light-permeable region 411 of the light-permeable sheet 4 faces toward the sensing region 211 of the sensor chip 2 (as shown in FIG. 11).

In summary, the steps in the manufacturing method of the sensing module provided by the present embodiment are implemented through certain components (e.g., the opaque adhesive layers 42) for enabling the SD step S130 to be applied to the light-permeable board 40, so that when the light-permeable board 40 is cracked to become the light-permeable sheets 41, material loss of the light-permeable board 40 can be greatly reduced to effectively decrease production costs. Moreover, the manufacturing method of the sensing module in the present embodiment can be implemented to provide the cap 4 having adhering function, thereby facilitating the production and manufacturing of a sensing module M.

### Sensor Package Structure

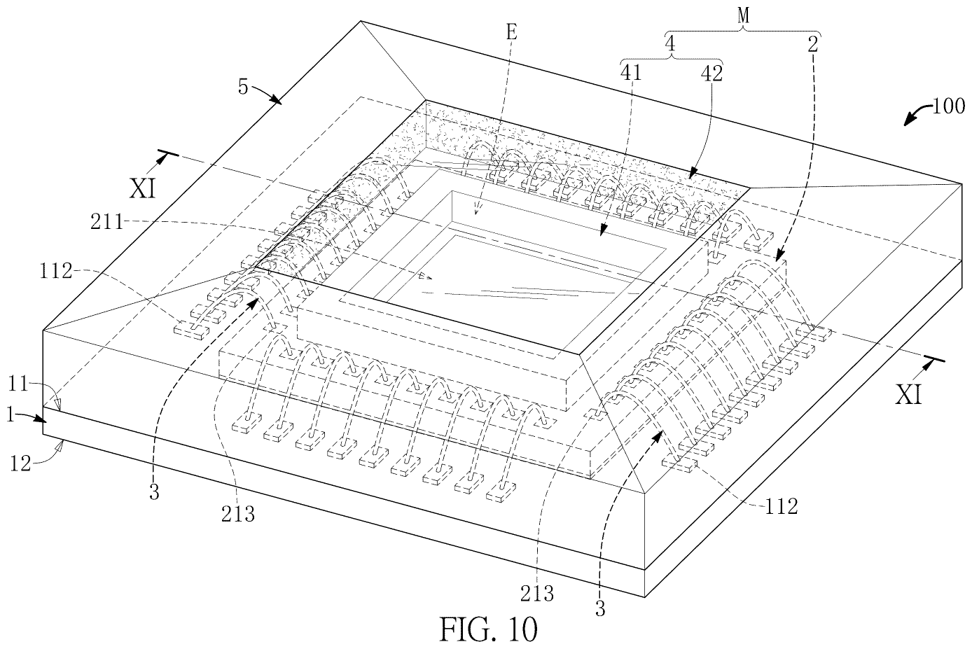

As shown in FIG. 10 to FIG. 12, the present embodiment further provides a sensor package structure 100, which includes a substrate 1, a sensor chip 2, a plurality of metal wires 3 electrically coupled to the sensor chip 2 and the substrate 1, a cap 4 assembled to the sensor chip 2, and an encapsulant 5 that is formed on the substrate 1, but the present disclosure is not limited thereto. For example, in other embodiments of the present disclosure not shown in the drawings, the sensor chip 2 can be fixed onto and electrically coupled to the substrate 1 in a flip-chip manner according to practical requirements, such that the sensor package structure 100 can be provided without the metal wires 3.

In addition, the sensor chip 2 and the cap 4 can be jointly defined as a sensing module M that is preferably provided by implementing the manufacturing method described in the above description, and the sensor package structure 100 is manufactured by mounting the sensor chip 2 of the cap 4 onto the substrate 1 and forming the metal wires 3 and the encapsulant 5, but the present disclosure is not limited thereto. For example, in other embodiments of the present disclosure not shown in the drawings, the sensing module M or the sensor package structure 100 can be manufactured by implementing a method other than the manufacturing method of the present embodiment.

Moreover, the sensing module M in the present embodiment is described in cooperation with the substrate 1, the metal wires 3, and the encapsulant 5, but the present disclosure is not limited thereto. For example, in other embodiments of the present disclosure not shown in the drawings, the sensing module M can be independently used (e.g., sold) or can be used in cooperation with other components. The following description describes the structure and connection relationship of components of the sensor package structure 100 provided by the present embodiment.

The substrate 1 of the present embodiment has a square shape or a rectangular shape, but the present disclosure is not limited thereto. The substrate 1 has a first surface 11 and a second surface 12 that is opposite to the first surface 11. The first surface 11 of the substrate 1 includes a chip-bonding region 111 arranged approximately on a center portion thereof, and the substrate 1 includes a plurality of bonding pads 112 that are disposed on the first surface 11 and are arranged outside of the chip-bonding region 111. The bonding pads 112 in the present embodiment are in an annular arrangement, but the present disclosure is not limited thereto. For example, in other embodiments of the present disclosure not shown in the drawings, the bonding pads 112 can be arranged in two rows respectively at two opposite sides of the chip-bonding region 111.

In addition, the substrate 1 in the present embodiment can be further provided with a plurality of solder balls 6 disposed on the second surface 12 thereof. The substrate 1 can be soldered onto an electronic component (not shown in the drawings) through the solder balls 6, thereby electrically connecting the sensor package structure 100 to the electronic component.

The sensor chip 2 in the present embodiment is an image sensing chip, but the present disclosure is not limited thereto. The sensor chip 2 is fixed onto the first surface 11 of the substrate 1 (e.g., the chip-bonding region 111) through a bottom surface 22 thereof. In other words, the sensor chip 2 is arranged to be surrounded on the inside of the bonding pads 112. It should be noted that the sensor package structure 100 in the present embodiment includes an adhesive (not labeled in the drawings) disposed on the chip-bonding region 111, and the sensor chip 2 is fixed onto the chip-bonding region 111 through the adhesive, but the present disclosure is not limited thereto. For example, in other embodiments of the present disclosure not shown in the drawings, the adhesive can be omitted or can be replaced by other components.

Moreover, a top surface 21 of the sensor chip 2 has a sensing region 211 and a carrying region 212 that has an annular shape surrounding the sensing region 211. The sensor chip 2 in the present embodiment includes a plurality of connection pads 213 arranged on the carrying region 212. Moreover, the number and positions of the connection pads 213 of the sensor chip 2 in the present embodiment correspond to those of the bonding pads 112 of the substrate 1. In other words, the connection pads 213 are in an annular arrangement, and a quantity of the connection pads 213 is equal to a quantity of the bonding pads 112.

Each of the metal wires 3 has two ends, one of the two ends of each of the metal wires 3 is connected to one of the bonding pads 112, and another one of the two ends of each of the metal wires 3 is connected to one of the connection pads 213, so that the substrate 1 and the sensor chip 2 can be electrically connected to each other through the metal wires 3. Any one of the metal wires 3 can be configured in a normal bonding manner or a reverse bonding manner according to design requirements, and the present disclosure is not limited thereto.

The cap 4 includes a light-permeable sheet 41 and an opaque adhesive layer 42 that is adhered to the light-permeable sheet 41. The light-permeable sheet 41 in the present embodiment is a transparent and flat glass board, but the present disclosure is not limited thereto. Moreover, the light-permeable sheet 41 has an inner surface 411, an outer surface 412 that is opposite to the inner surface 411, and a plurality of lateral surfaces that connected in-between the inner surface 411 and the outer surface 412.

It should be noted that each of at least two of the lateral surfaces 413 of the light-permeable sheet 41 is a cracked rough surface. In the present embodiment, each of the lateral surfaces 413 of the light-permeable sheet 41 is preferably the cracked rough surface. Moreover, any one of the cracked rough surfaces of the light-permeable sheet 41 has a plurality of first modified points 4131 and a plurality of second modified points 4132. The first modified points 4131 are located at a first depth D1 relative to the inner surface 411, and the second modified points 4132 are located at a second depth D2 relative to the inner surface 411.

In the present embodiment, any one of the cracked rough surfaces of the light-permeable sheet 41 further has a plurality of third modified points 4133 that are located at a third depth D3 relative to the inner surface 411. In other words, any one of the first modified points 4131 and an adjacent one of the second modified points 4132 are provided with at least one of the third modified points 4133 therebetween. Moreover, at least one of the third modified points 4133 is spaced apart from an adjacent one of the first modified points 4131 and an adjacent one of the second modified points 4132 by a same distance, but the present disclosure is not limited thereto. In other embodiments of the present disclosure not shown in the drawings, a quantity of the at least one third modified point 4133 between any one of the first modified points 4131 and an adjacent one of the second modified points 4132 can be more than one, and the third modified points 4133 being arranged at different depths.

In addition, the inner surface 411 of the light-permeable sheet 41 has a light-permeable region 4111 and a processing region 4112 that surrounds the light-permeable region 4111. The opaque adhesive layer 42 is ring-shaped and is adhered onto the processing region 4112 of the inner surface 411 of the light-permeable sheet 41 (e.g., the opaque adhesive layer 42 surrounds light-permeable region 4111). In the present embodiment, any one of the cracked rough surfaces of the light-permeable sheet 41 is spaced apart from the opaque adhesive layer 42 by a shortest distance S that is less than or equal to 45 μm. The shortest distance S is preferably within a range from 5 μm to 15 μm, but the present disclosure is not limited thereto.

It should be noted the opaque adhesive layer 42 (e.g., a black adhesive layer) in the present embodiment is sticky and can block visible light from passing therethrough, but the opaque adhesive layer allows a laser beam 201 emitted from a SD apparatus 200 to pass therethrough (as shown in FIG. 6). In other words, the opaque adhesive layer 42 provided by the present embodiment is different from a shielding layer that allows visible light to pass therethrough, that does not allow the laser beam 201 to pass therethrough, or that is not sticky.

The cap 4 is adhered onto the carrying region 212 of the sensor chip 2 through the opaque adhesive layer 42, and the connection pads 213 are located outside of the opaque adhesive layer 42, so that the cap 4 and the top surface 21 of the sensor chip 2 jointly define an enclosed space E, and the light-permeable region 4111 of the light-permeable sheet 41 faces toward the sensing region 211 of the sensor chip 2.

Moreover, the encapsulant 5 is formed on the first surface 11 of the substrate 1. The sensor chip 2, the cap 4, and the metal wires 3 are embedded in the encapsulant 5, and at least part of the outer surface 412 of the light-permeable sheet 41 is exposed from the encapsulant 5. It should be noted that any one of the lateral surfaces 413 of the light-permeable sheet 41 can be roughened by forming a plurality of modified points (e.g., the first modified points 4131, the second modified points 4132, and the third modified points 4133). Accordingly, the modified points of the light-permeable sheet 41 in the present embodiment are embedded in the encapsulant 5, such that the combining strength between the light-permeable sheet 41 and the encapsulant 5 can be increased, and a flare issue generated from the lateral surfaces 413 can be effectively improved.

In addition, the encapsulant 5 in the present embodiment is a molding compound, but the present disclosure is not limited thereto. For example, in other embodiments of the present disclosure not shown in the drawings, according to practical requirements, the encapsulant 5 can be a solidified liquid compound; or, the encapsulant 5 can include a solidified liquid compound and a molding compound that is formed on a top surface of the solidified liquid compound.

### Beneficial Effects of the Embodiment

In conclusion, the steps in the manufacturing method of the sensing module provided by the present disclosure are implemented through certain components (e.g., the opaque adhesive layers) for enabling the SD step to be applied to the light-permeable board, so that when the light-permeable board is cracked to become the light-permeable sheets, material loss of the light-permeable board can be greatly reduced to effectively decrease production costs.

Moreover, the sensor package structure, the manufacturing method, and the sensing module in the present disclosure can be implemented to enable the sensor chip to be assembled with the cap having an adhering function, thereby facilitating the production and manufacturing of the sensing module (or the sensor package structure).

In addition, at least two of the lateral surfaces of the light-permeable sheet in the sensor package structure provided by the present disclosure are roughened by forming a plurality of modified points that are embedded in the encapsulant, such that the combining strength between the light-permeable sheet and the encapsulant can be increased, and a flare issue generated from the lateral surfaces can be effectively improved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A manufacturing method of a sensing module, comprising:
a preparing step implemented by attaching an outer surface of a light-permeable board onto a tape, wherein the light-permeable board defines a plurality of processing paths that jointly define a plurality of light-permeable sheets connected to each other, and wherein an inner surface of each of the light-permeable sheets has a light-permeable region and a processing region that surrounds the light-permeable region;
an adhesive placing step implemented by respectively disposing a plurality of opaque adhesive layers on the processing regions of the light-permeable sheets, wherein each of the opaque adhesive layers surrounds the light-permeable region of a corresponding one of the light-permeable sheets and allows a laser beam to pass therethrough, wherein the opaque adhesive layers are spaced apart from each other, and any two of the opaque adhesive layers adjacent to each other have a gap therebetween, and wherein a width of each of the gaps is less than or equal to 90 μm, and the processing paths are arranged in the gaps;
a stealth dicing (SD) step implemented by emitting the laser beam onto the light-permeable board along the processing paths so as to form a plurality of first modified points in an interior of the light-permeable board at a first depth and a plurality of second modified points in the interior of the light-permeable board at a second depth that is different from the first depth;
a cracking step implemented by stretching the tape to crack the light-permeable board into the light-permeable sheets along the processing paths through the first modified points and the second modified points, wherein each of the light-permeable sheets and the corresponding opaque adhesive layer adhered thereon are jointly defined as one of a plurality of caps; and
a bonding step implemented by attaching one of the caps onto a sensor chip through the opaque adhesive layer thereof that surrounds a sensing region of the sensor chip, such that the one of the caps and the sensor chip jointly define an enclosed space, and the light-permeable region of the light-permeable sheet faces toward the sensing region of the sensor chip.

2. The manufacturing method according to claim 1, wherein, in the SD step, the laser beam is emitted onto the light-permeable board along the processing paths so as to form at least one third modified point in the interior of the light-permeable board between any one of the first modified points and an adjacent one of the second modified points.

3. The manufacturing method according to claim 2, wherein the at least one third modified point is spaced apart from an adjacent one of the first modified points and an adjacent one of the second modified points by a same distance.

4. The manufacturing method according to claim 1, wherein, in the SD step, the laser beam passing through any one of the opaque adhesive layers focuses on the interior of the light-permeable board to form at least one of the first modified points and the second modified points.

5. The manufacturing method according to claim 1, wherein the width of each of the gaps is within a range from 10 μm to 30 μm.

6. A sensor package structure, comprising:
a substrate having a first surface and a second surface that is opposite to the first surface;
a sensor chip mounted on the first surface of the substrate and electrically coupled to the substrate, wherein a top surface of the sensor chip has a sensing region and a carrying region that is arranged outside of the sensing region;
a cap including:
a light-permeable sheet having an inner surface and an outer surface that is opposite to the inner surface, wherein the inner surface has a light-permeable region and a processing region that surrounds the light-permeable region; and
an opaque adhesive layer being ring-shaped and adhered onto the processing region of the inner surface of the light-permeable sheet, wherein the opaque adhesive layer is configured to allow a laser beam to pass therethrough;
wherein the cap is adhered onto the carrying region of the sensor chip through the opaque adhesive layer, the cap and the top surface of the sensor chip jointly define an enclosed space, and the light-permeable region of the light-permeable sheet faces toward the sensing region of the sensor chip; and
an encapsulant formed on the first surface of the substrate, wherein the sensor chip and the cap are embedded in the encapsulant, and at least part of the outer surface of the light-permeable sheet is exposed from the encapsulant.

7. The sensor package structure according to claim 6, wherein the light-permeable sheet has a plurality of lateral surfaces connected in-between the inner surface and the outer surface, and each of at least two of the lateral surfaces is a cracked rough surface.

8. The sensor package structure according to claim 7, wherein any one of the cracked rough surfaces of the light-permeable sheet has:
a plurality of first modified points located at a first depth relative to the inner surface; and
a plurality of second modified points located at a second depth relative to the inner surface.

9. The sensor package structure according to claim 7, wherein any one of the cracked rough surfaces of the light-permeable sheet is spaced apart from the opaque adhesive layer by a shortest distance that is less than or equal to 45 μm.

10. The sensor package structure according to claim 7, wherein any one of the cracked rough surfaces of the light-permeable sheet is spaced apart from the opaque adhesive layer by a shortest distance that is within a range from 5 μm to 15 μm.

11. The sensor package structure according to claim 6, wherein the substrate includes a plurality of bonding pads arranged on the first surface, the sensor chip includes a plurality of connection pads arranged on the carrying region and located outside of the opaque adhesive layer, wherein the sensor package structure includes a plurality of metal wires embedded in the encapsulant, and wherein one end of the metal wires is connected to the bonding pads, and another end of the metal wires is connected to the connection pads.

12. A sensing module, comprising:
a sensor chip, wherein a top surface of the sensor chip has a sensing region and a carrying region that is arranged outside of the sensing region; and
a cap including:
a light-permeable sheet having an inner surface and an outer surface that is opposite to the inner surface, wherein the inner surface has a light-permeable region and a processing region that surrounds the light-permeable region; and
an opaque adhesive layer being ring-shaped and adhered onto the processing region of the inner surface of the light-permeable sheet, wherein the opaque adhesive layer is configured to allow a laser beam to pass therethrough;
wherein the cap is adhered onto the carrying region of the sensor chip through the opaque adhesive layer, the cap and the top surface of the sensor chip jointly define an enclosed space, and the light-permeable region of the light-permeable sheet faces toward the sensing region of the sensor chip.

13. The sensing module according to claim 12, wherein the light-permeable sheet has a plurality of lateral surfaces connected in-between the inner surface and the outer surface, and each of at least two of the lateral surfaces is a cracked rough surface.

14. The sensing module according to claim 13, wherein any one of the cracked rough surfaces of the light-permeable sheet has:
a plurality of first modified points located at a first depth relative to the inner surface; and
a plurality of second modified points located at a second depth relative to the inner surface.

15. The sensing module according to claim 13, wherein any one of the cracked rough surfaces of the light-permeable sheet is spaced apart from the opaque adhesive layer by a shortest distance that is less than or equal to 45 μm.
